(19) United States
(12) Patent Application Publication
(10) Pub. No.: US 2014/0103412 A1
(43) Pub. Date: Apr. 17, 2014

(54) THREE-DIMENSIONAL IMAGE SENSORS AND METHODS OF FABRICATING THE SAME

(71) Applicant: SAMSUNG ELECTRONICS CO., LTD., Suwon-Si (KR)

(72) Inventors: KWANG-MIN LEE, SEOUL (KR); WONJOO KIM, HWASEONG-SI, GYEONGGI-DO (KR); DOOCHEOL PARK, HWASEONG-SI, GYEONGGI-DO (KR); JUNG BIN YUN, HWASEONG-SI, GYEONGGI-DO (KR); JUNGWOOK LIM, YONGIN-SI, GYEONGGI-DO (KR)

(73) Assignee: SAMSUNG ELECTRONICS CO., LTD., Suwon-Si (KR)

(21) Appl. No.: 14/037,691

(22) Filed: Sep. 26, 2013

(30) Foreign Application Priority Data
Oct. 15, 2012 (KR) 10-2012-0114308

(51) Int. Cl. H01L 27/146

(52) U.S. Cl. CPC H01L 27/14643
USPC 257/292

(57) ABSTRACT

A three-dimensional image sensor includes a first photoelectric converter in a first pixel region of a substrate, a second photoelectric converter in a second pixel region of the substrate, a first transfer gate structure disposed on the substrate at one side of the first photoelectric converter, a second transfer gate structure and a drain gate structure disposed on the substrate at opposite sides of the second photoelectric converter and whose gate insulating layers are thinner the gate insulating layer of the first transfer gate structure. The gate insulating layers can be fabricated by forming a first insulating layer on the pixel regions of the substrate, removing part of the first insulating layer from the second pixel region, and subsequently forming a second insulating layer on the substrate including over a part of the first insulating layer which remains on the first pixel region.

### PRIORITY STATEMENT

This U.S. non-provisional patent application claims priority under 35 U.S.C. §119 to Korean Patent Application No. 10-2012-0114308, filed on Oct. 15, 2012, in the Korean Intellectual Property Office, the entire contents of which are hereby incorporated by reference.

### BACKGROUND

The inventive concept relates to three-dimensional image sensors and methods of fabricating the same.

There are many types of conventional imaging devices which use photo sensors to convert the image of an object into electric signals, and which process the signals to re-produce an image of the object in two dimensions. Recently, however, the applications of imaging devices have been expanded by the development of three-dimensional (3D) image sensors which acquire depth information of an object, in addition to conventional image information. The depth information is used by the imaging device to re-produce a 3D image of the object. A 3D image may be a composite of a color image and a depth image. The depth image may be obtained using a time-of-flight (TOF) technique. One example of a 3D imaging device is an infrared-based camera. In an infrared-based camera, an object is illuminated with infrared rays, and the TOF of the light reflected from the object is used to calculate the distance from the camera to the object. The calculated distance is used as depth information for producing the depth image.

### SUMMARY

According to an aspect of the inventive concept, there is provided a three-dimensional (3D) image sensor comprising a substrate including a first pixel region and a second pixel region, a first photoelectric converter in the first pixel region of the substrate, a second photoelectric converter in the second pixel region of the substrate, a first transfer gate disposed on the substrate at one side of the first photoelectric converter, a first transfer gate insulating layer interposed between the first transfer gate and the substrate, a second transfer gate disposed on the substrate at one side of the second photoelectric converter, a second transfer gate insulating layer interposed between the second transfer gate and the substrate, a drain gate disposed on the substrate at other side of the second photoelectric converter, a drain gate insulating layer interposed between the second transfer gate and the substrate, and in which the second transfer gate insulating layer and the drain gate insulating layer each have a thickness different from that of the first transfer gate insulating layer.

According to another aspect of the inventive concept, there is provided a three-dimensional (3D) image sensor comprising a semiconductor substrate, a device isolation layer in the substrate and defining a first active region and a second active region, a color pixel configured to output color information of an object, and a depth pixel configured to output information on the relative depth of the object and which the color pixel includes a first transfer gate electrode on the first active region, first transfer gate insulation interposed between and contacting the first transfer gate electrode and the first active region, a first photoelectric converter that converts light to electrical signals, and a first floating diffusion region, the first photoelectric converter includes a region of impurities located in the first active region and extending at one side of the first transfer gate electrode, the first floating diffusion region is located in the first active region at the other side of the first transfer gate electrode, the depth pixel includes a second transfer gate electrode disposed on the second active region, second transfer gate insulation interposed between and contacting the second transfer gate electrode and the second active region, a second floating diffusion region, a drain gate electrode disposed on the second active region, drain gate insulation interposed between the drain gate electrode and the second active region, a drain region, and a second photoelectric converter that converts light to electrical signals, the second photoelectric converter includes a region of impurities in the second active region and extending to one side each of the second transfer gate electrode and the drain gate electrode, the second floating diffusion region is located in the second active region at the other side of the second transfer gate electrode, the drain region is located in the second active region at the other side of the drain gate electrode, and at least one of the drain gate insulation and the second transfer gate insulation is thinner than the first transfer gate insulation.

According to still another aspect of the inventive concept, there is provided a method of fabricating a three-dimensional image sensor, in which a first photoelectric converter and a second photoelectric converter are formed in first and second pixel regions of a substrate, respectively, a first gate insulating layer and a second gate insulating layer are formed on the first and second photoelectric conversion parts, respectively, a first transfer gate is formed on the first gate insulating layer, and a drain electrode and a second transfer gate are formed on the second gate insulating layer and as spaced apart from each other, and in which the first and second gate layers are carried out such that the drain gate and second transfer gate are not formed on the first gate insulating layer. Thus, the gate insulation between the substrate and the drain and second transfer gates is thinner than the gate insulation between the substrate and the first transfer gate.

### BRIEF DESCRIPTION OF THE DRAWINGS

The inventive concept will be more clearly understood from the following brief description of the preferred embodiments thereof taken in conjunction with the accompanying drawings.

FIG. 1 is a layout of a 3D image sensor according to of the inventive concept.

FIG. 2 is a sectional view taken along line I-I′ of FIG. 1.

FIGS. 3A and 3B are circuit diagrams of the image sensor of FIG. 1 illustrating circuits at a first pixel region and a second pixel region, respectively.

FIGS. 4, 5, 6 and 7 are sectional views that are taken in the direction of line I-I′ of FIG. 1 and which together illustrate a process of fabricating the 3D image sensor of FIG. 2.

FIG. 8 is a schematic block diagram of an imaging device, in which the 3D image sensor according to the inventive concept is used.

### DETAILED DESCRIPTION OF THE PREFERRED EMBODIMENT

Various embodiments and examples of embodiments of the inventive concept will be described more fully hereinafter with reference to the accompanying drawings. In the drawings, the sizes and relative sizes and shapes of elements, layers and regions, such as implanted regions, shown in section may be exaggerated for clarity. In particular, the cross-sectional illustrations of the semiconductor devices and intermediate structures fabricated during the course of their manufacture are schematic. Also, like numerals are used to designate like elements throughout the drawings.

It will also be understood that when an element or layer is referred to as being “on” or “connected to” another element or layer, it can be directly on or directly connected to the other element or layer or intervening elements or layers may be present. In contrast, when an element or layer is referred to as being “directly on”, “in contact with” or “directly connected to” another element or layer, there are no intervening elements or layers present.

It will also be understood that although the terms first, second, third etc. are used herein to describe various elements, regions, layers, etc., these elements, regions, and/or layers are not limited by these terms. These terms are only used to distinguish one element, layer or region from another.

Other terminology used herein for the purpose of describing particular examples or embodiments of the inventive concept is to be taken in context. For example, the terms “comprises” or “comprising” when used in this specification specifies the presence of stated features or processes but does not preclude the presence or additional features or processes.

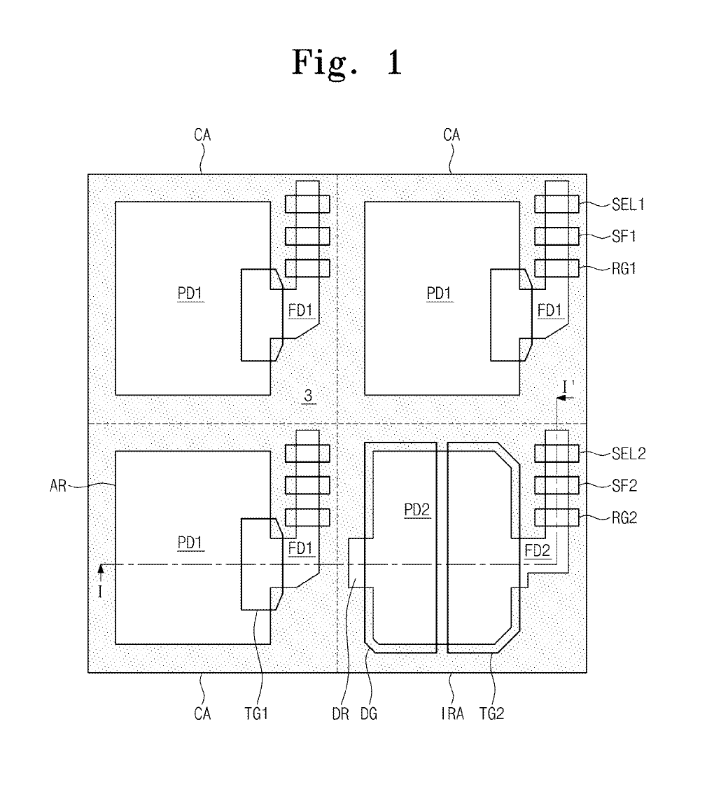

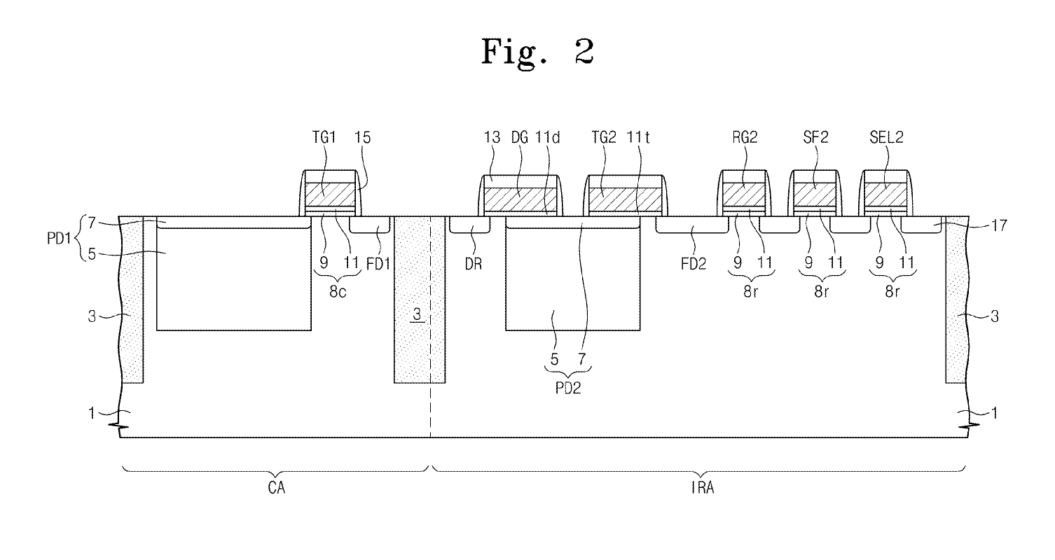

A 3D image sensor according to the inventive concept will now be described with reference to FIGS. 1 and 2.

This example of a 3D image sensor according to the inventive concept includes a substrate 1 having first pixel regions CA and a second pixel region IRA. The first pixel regions CA include color pixels configured to sense visible light, such as red, green, or blue light. The second pixel region IRA includes a depth pixel configured to sense infrared rays. A device isolation layer 3 may be provided in the substrate 1 to define active regions AR in each of the pixel regions CA and IRA. The substrate 1 may be a silicon wafer, silicon-on-insulator (SOI) wafer, or a substrate including a semiconductor epitaxial layer. The device isolation layer 3 may be formed of an insulating material having a different refractive index from the substrate 1. For example, the device isolation layer 3 may be formed of at least one material selected from the group consisting of silicon oxide, silicon nitride, and silicon oxynitride. The substrate 1 may be doped with p-type impurities, for example.

A first photoelectric conversion part (converter) PD1 and a second photoelectric conversion part (converter) PD2 are provided in the pixel regions CA and IRA, respectively, of the substrate 1. Each of the photoelectric conversion parts PD1 and PD2 include a first doped region 5 and a second doped region 7. For example, the first doped region 5 may contain n-type impurities, while the second doped region 7 may contain p-type impurities. In other words, each of the photoelectric conversion parts PD1 and PD2 may be a photodiode including the p-type region 7 and the n-type region 5.

Furthermore, the first pixel region CA and the second pixel region IRA may be different from each other in terms of the depth of their first doped regions 5. For example, the depth of the first doped region 5 may be greater in the second pixel region IRA than in the first pixel region CA.

A first transfer gate TG1 is provided on the substrate 1 beside the first photoelectric conversion part PD1. Furthermore, a first reset gate RG1, a first source follower gate SF1, and a first selection gate SEL1 may be provided on the substrate 1 as spaced apart from the first transfer gate TG1. A first floating diffusion region FD1 may be provided in the substrate 1 between the first transfer gate TG1 and the first reset gate RG1. In the first pixel region CA, a first gate insulating layer 8c may be provided between the first gates TG1, RG1, SF1, and SEL1 and the substrate 1. The first gate insulating layer 8c may be a dual layer consisting of a first insulating layer 9 and a second insulating layer 11. Here and from now on, the term “gate” will be understood as referring to a gate electrode, whereas the term “gate structure” may refer to a structure that includes a gate electrode and gate insulating layer. Thus, the first gate insulating layer 8c may refer to the totality of insulating material that is disposed in contact with both the active region of the substrate and the respective gate electrodes associated therewith.

A second transfer gate TG2 is provided on the substrate 1 at one side of the second photoelectric conversion part PD2, and a drain gate DG is provided on the substrate 1 at other side of the second photoelectric conversion part PD2. A second reset gate RG2, a second source follower gate SF2, and a second selection gate SEL2 are provided on the substrate 1 as spaced apart from the second transfer gate TG2. A second floating diffusion region FD2 is provided in the substrate 1 between the second transfer gate TG2 and the second reset gate RG2. Source/drain regions 17 are provided in portions of the substrate 1 that are adjacent to sidewalls of the reset gates RG1 and RG2, the source follower gates SF1 and SF2, and the selection gates SEL1 and SEL2. A depth drain region DR is provided in a portion of the substrate 1 that is adjacent to the drain gate DG, and is spaced apart from the second photoelectric conversion part PD2.

A second transfer gate insulating layer 11t is interposed between the second transfer gate TG2 and the substrate 1, and a drain gate insulating layer 11d is interposed between the drain gate DG and the substrate 1. The second transfer gate insulating layer 11t and the drain gate insulating layer 11d may be formed of a single layer. A second gate insulating layer 8r is provided between the second reset gate RG2 and the substrate 1, between the second source follower gate SF2 and the substrate 1, and between the second selection gate SEL2 and the substrate 1. The second gate insulating layer 8r may be a dual layer including a first insulating layer 9 and a second insulating layer 11. In this respect, the first gate insulating layer 8c may have the same composition (structure, materials, etc.) as the second gate insulating layer 8r. In this case as well, the term “gate” will be understood as referring to an electrode.

Although not shown, contact plugs and wires may be provided on the substrate 1 to form an electrical interconnection between the gate electrodes TG1, TG2, RG1, RG2, SF1, SF2, SEL1, SEL2, and DG and the doped regions FD1, FD2, 17, and DR. Moreover, an interlayer insulating layer may be provided to cover the resulting structure. Infrared ray filters, color filters, and micro lenses may be provided on the interlayer insulating layer or on the bottom surface of the substrate 1. In this case, each infrared ray filter overlaps a second pixel region IRA, while each color filter overlaps a first pixel region CA.

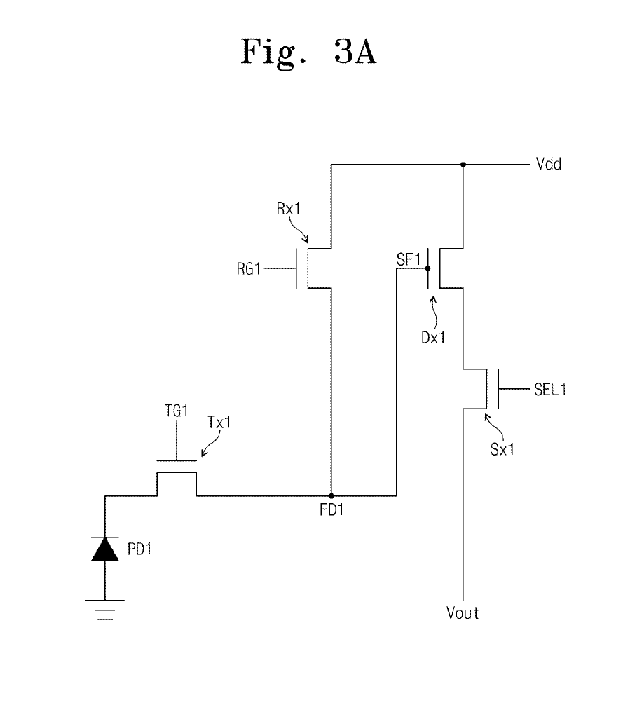

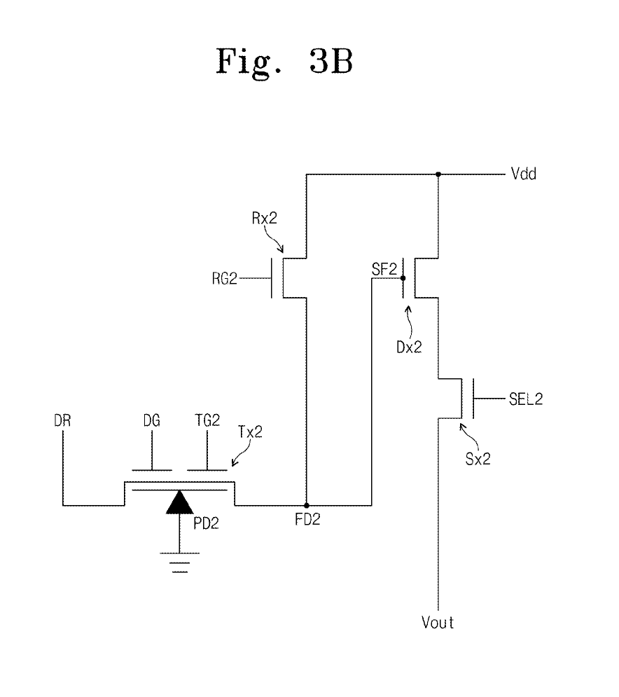

FIGS. 3A and 3B are circuit diagrams of the first and second pixel regions, respectively, of FIG. 1.

Referring to FIGS. 1, 2, and 3A, in this example of the 3D image sensor, a color pixel includes the first photoelectric conversion part PD1, a first transfer transistor Tx1, a first source follower transistor Dx1, a first reset transistor Rx1, and a first selection transistor Sx1. The first transfer transistor Tx1, the first source follower transistor Dx1, the first reset transistor Rx1, and the first selection transistor Sx1 are constituted by the first transfer gate TG1, the first source follower gate SF1, the first reset gate RG1, and the first selection gate SEL1, respectively. The first floating diffusion region FD1 serves as a drain electrode of the first transfer transistor Tx1 and a source electrode of the first reset transistor Rx1. The first floating diffusion region FD1 is electrically connected to the first source follower gate SF1 of the first source follower transistor Dx1. The first source follower transistor Dx1 is connected to the first selection transistor Sx1.

In another example, at least one of the first reset transistor Rx1, the first source follower transistor Dx1, and the first selection transistor Sx1 is shared by at least one pair of neighboring pixels. This allows for an integration density of the device to be increased.

Hereinafter, the operation of a color pixel of the image sensor, i.e., the function of the first pixel region CA, will be briefly described with reference to FIG. 3A. Firstly, in a light-blocking condition, a power voltage VDD is applied to the drain of the first reset transistor Rx1 and the drain of the first source follower transistor Dx1, thereby exhausting electric charges from the first floating diffusion region FD1. Subsequently, the first reset transistor Rx1 is turned off and external light incident on the first photoelectric conversion part PD1 generates electron-hole pairs in the first photoelectric conversion part PD1. As a result, holes and electrons move toward and accumulate in the p-type and n-type doped regions 5 and 7 of the first photoelectric conversion part PD1, respectively. If the first transfer transistor Tx1 is turned on, the electric charges such as electrons and holes move to and accumulate in the first floating diffusion region FD1. The presence of a sufficient number of accumulated electric charge changes the gate voltage of the first source follower transistor Dx1. Then, if the first selection transistor Sx1 is turned-on, a signal can be read out through a column line.

Referring to FIGS. 1, 2, and 3B, an example of the depth pixel of the 3D image sensor includes the second photoelectric conversion part PD2, a second transfer transistor Tx2, a second source follower transistor Dx2, a second reset transistor Rx2, and a second selection transistor Sx2 at an upper portion of the second pixel region IRA. The second transfer transistor Tx2, the second source follower transistor Dx2, the second reset transistor Rx2, and the second selection transistor Sx2 are constituted by the second transfer gate TG2, the second source follower gate SF2, the second reset gate RG2, and the second selection gate SEL2, respectively. The second floating diffusion region FD2 serve as a drain electrode of the second transfer transistor Tx2. The second transfer gate TG2 and the drain gate DG are provided on the second photoelectric conversion part PD2.

The second transistors Tx2, Rx2, Dx2, and Sx2 in the second pixel region IRA are operated in a similar manner to those of the first transistors Tx1, Rx1, Dx1, and Sx1 in the first pixel region, with the following exceptions. One is that a switching frequency of the second transfer gate TG2 is greater than that of the first transfer gate TG1. For example, the switching frequency of the first transfer gate TG1 is four times that of the second transfer gate TG2. In addition, the drain gate DG is operated in a reverse manner with respect to the second transfer gate TG2. For example, if the second transfer gate TG2 is turned on (in an ON state), the drain gate DG is turned off (in an OFF state). If the second transfer gate TG2 is turned on, electric charges stored in the second photoelectric conversion part PD2 move into the second floating diffusion region FD2, and the second transistors Rx2, Dx2, and Sx2 operate in the same manner as the first transistors Rx1, Dx1, and Sx1, as described above. If the second transfer gate TG2 is turned off, the drain gate DG is turned on, thereby exhausting or discharging electric charges, which were not moved into the second floating diffusion region FD2, from the second photoelectric conversion part PD2 to the outside through the depth drain region DR. In the imaging device employing an embodiment of a 3D image sensor, according to the inventive concept, the discharged electric charges are sensed.

The drain gate DG and the second transfer gate TG2 have the potential to serve as major sources of power consumption in the 3D image sensor because they have faster operation speeds or shorter operation periods than those of other gates TG1, RG1, RG2, SF1, SF2, SEL1, and SEL2.

However, according to an aspect of the inventive concept, the second transfer gate insulating layer 11t and the drain gate insulating layer 11d are thinner than the first gate insulating layer 8c and the second gate insulating layer 8r. Accordingly, the operation voltages of the second transfer gate and the drain gate can be minimized. For example, if the thicknesses of the second transfer gate insulating layer 11t and the drain gate insulating layer 11d are about one-third of those of the first gate insulating layer 8c and the second gate insulating layer 8r, the operation voltages of the second transfer gate and the drain gate can be about one third those of a comparable sensor in which the thicknesses of gate insulating layers are all the same. Accordingly, an imaging device according to the inventive concept may have low power consumption.

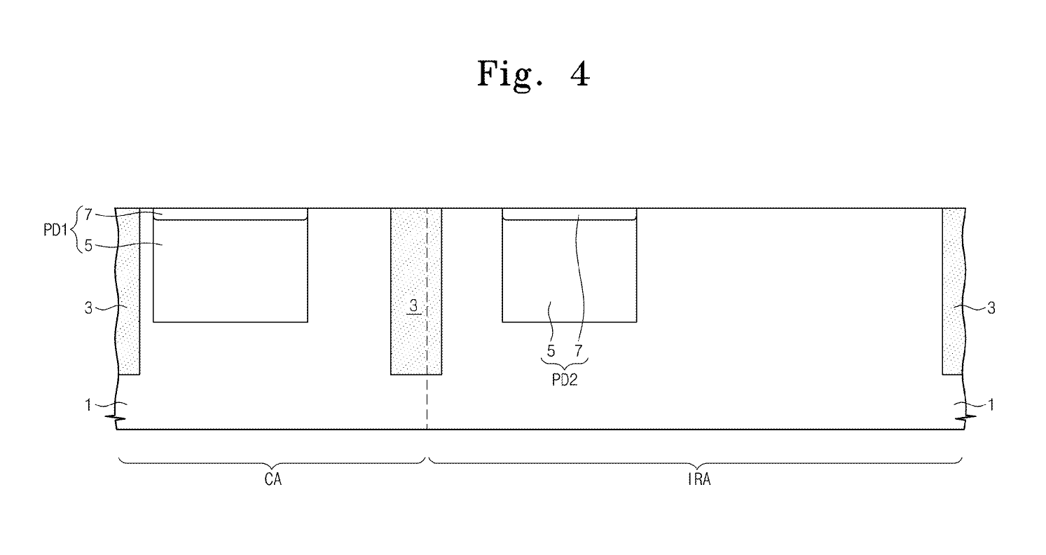

An example of a method of fabricating the 3D image sensor of FIG. 2 will now be described with reference to FIGS. 4 through 7.

Referring first to FIG. 4, the substrate 1 is prepared. For example, a bulk substrate or semiconductor layer is doped with p-type impurities. Also, the device isolation layer 3 is formed in the substrate 1 to define the active regions AR. The device isolation layer 3 may be formed using a shallow trench isolation (STI) or deep trench isolation (DTI) process. The device isolation layer 3 may be formed of at least one of a silicon oxide layer, a silicon nitride layer, and a silicon oxynitride layer. Still further, ions are implanted in the substrate 1, i.e., ion implantation processes are performed, to form the first doped region 5 and the second doped region 7 of each of the first and second photoelectric conversion parts PD1 and PD2. The first doped region 5 may be formed by doping the substrate 1 with, for example, n-type impurities, while the second doped region 7 may be formed by doping the substrate 1 with, for example, p-type impurities.

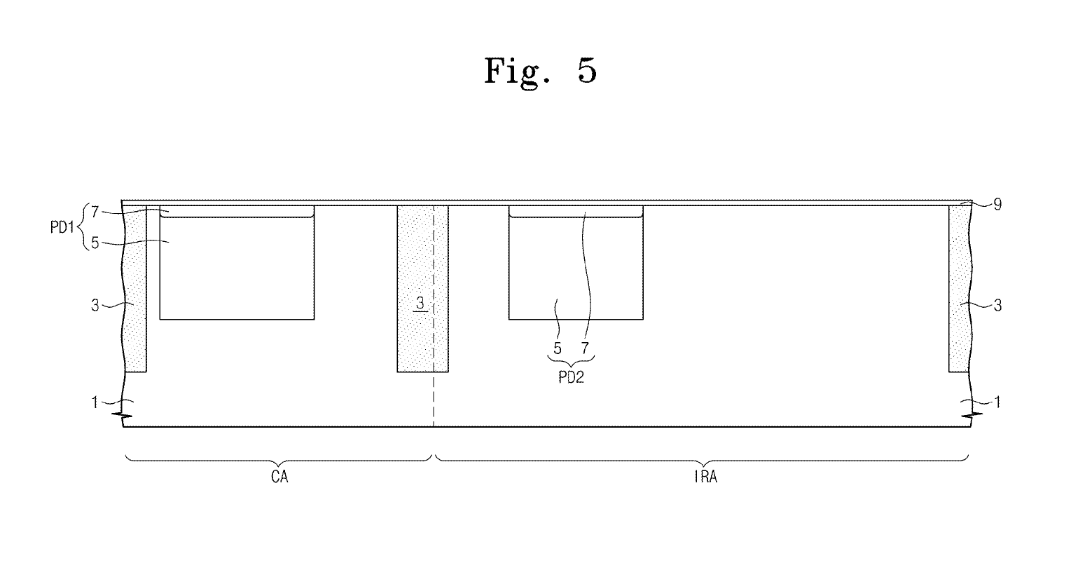

Referring to FIG. 5, the first insulating layer 9 is formed on the substrate 1. The first insulating layer 9 may be, for example, a silicon oxide layer. The first insulating layer 9 may be formed using a thermal oxidation process or a deposition process such as a chemical vapor deposition (CVD).

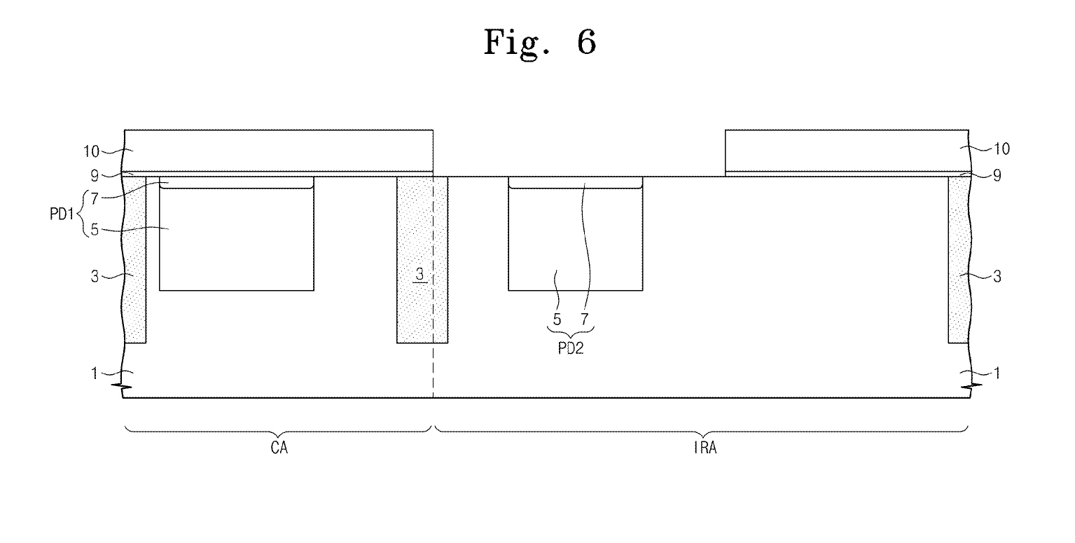

Referring to FIG. 6, a first mask pattern 10 is formed on the substrate 1 to cover the region of the substrate other than that at which the second photoelectric conversion part PD2 is provided and which may include regions just to the sides of the second photoelectric conversion part PD2. The first mask pattern 10 is formed of a material (e.g., a silicon nitride layer or a photoresist pattern) having an etch selectivity with respect to the first insulating layer 9. The first insulating layer 9 is then etched using the first mask pattern 10 as an etch mask to expose the second photoelectric conversion part PD2.

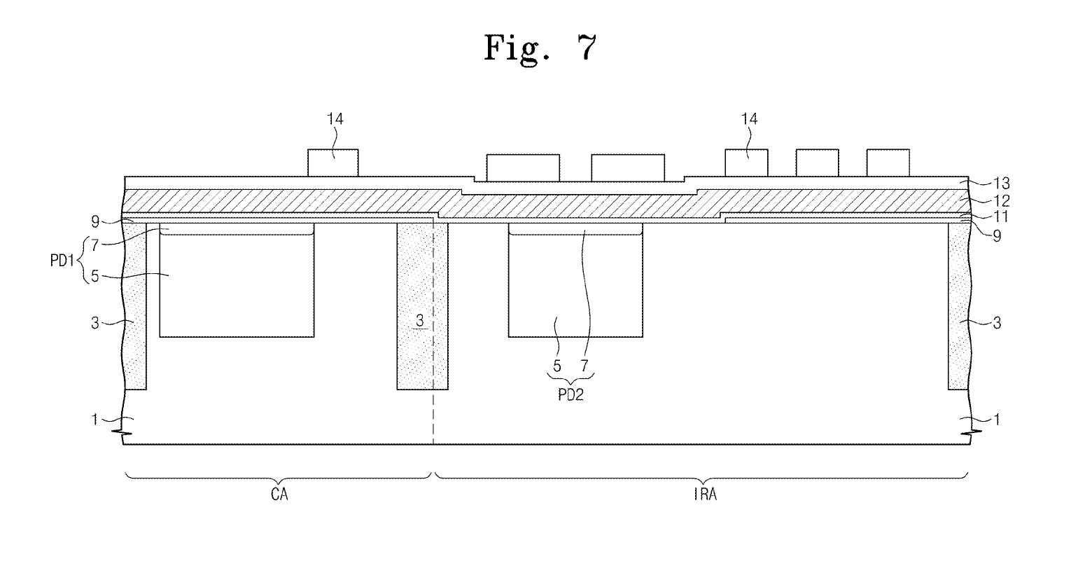

Referring to FIG. 7, the second insulating layer 11 is then formed on the substrate 1. The second insulating layer 11 may be a silicon oxide layer and may be formed using a deposition process, such as a chemical vapor deposition (CVD). As a result, the second insulating layer 11 constitutes a single-layered structure on the second photoelectric conversion part PD2, whereas a multi-layered (dual) structure consisting of the first insulating layer 9 and the second insulating layer 11 is provided over the remainder of the substrate 1. A conductive layer 12 and a capping layer 13 may be sequentially formed on the second insulating layer 11. The conductive layer 12 may be formed of a conductive material, such as doped polysilicon, aluminum, tungsten, or copper. The capping layer 13 may be, for example, a silicon nitride layer.

Next, in the above-described example, second mask patterns 14 are formed on the capping layer 13. The capping layer 13, the conductive layer 12, the second insulating layer 11, and the first insulating layer 9 are patterned using the second mask patterns 14 as an etch mask to form the gates TG1, TG2, RG1, RG2, SF1, SF2, SEL1, SEL2, and DG.

Subsequently, as shown in FIG. 2, spacers 15 may be formed on sidewalls of the gates TG1, TG2, RG1, RG2, SF1, SF2, SEL1, SEL2, and DG, and source/drain regions FD1, FD2, 17, and DR may be formed in the substrate 1 adjacent thereto. Furthermore, and although not shown, contact plugs, wires, an interlayer insulating layer, color filters, infrared ray filters and micro lenses are formed.

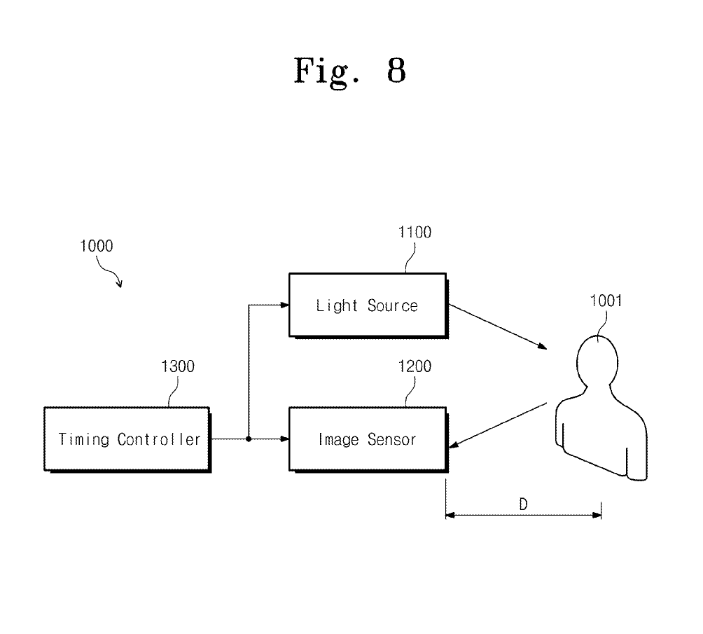

An imaging device 1000, which employs a 3D image sensor according to the inventive concept, is shown schematically in FIG. 8. The imaging device 1000 basically is configured to illuminate an object 1001, to sense the light reflected from the object 1001, and to determine the relative depth of respective parts of the object 1001 from the sensed light.

To this end, the imaging device 1000 includes a light source 1100 for illuminating the object 1001 with pulses of light including infrared rays, an image sensor 1200 that senses the light reflected from the object, and a timing controller 1300 that synchronizes operations of the light source 1100 and the image sensor 1200.

The image sensor 1200 is a 3D image sensor according to the inventive concept. Thus, the image sensor 1200 may detect infrared rays reflected from the object 1001 and output information on the optical depth of the object 1001. The optical depth information obtained from the 3D image sensor 1200 is used to realize 3D images, as in an infrared ray camera. In addition, it is possible to realize 3D color images because the 3D image sensor 1200 is configured to include infrared ray pixels and visible ray pixels.

According to an aspect of the inventive concept as described above, although the second transfer gate and the drain gate are required to operate at faster speeds than the other gates, the gate insulating layers of the second transfer gate and the drain gate are thinner than the other gate insulating layers. Accordingly, operation voltages of the second transfer gate and the drain gate may be kept to a minimum. As a result, a 3D image sensor according to the inventive concept is power efficient.

Finally, embodiments of the inventive concept and examples thereof have been described above in detail. The inventive concept may, however, be embodied in many different forms and should not be construed as being limited to the embodiments described above. Rather, these embodiments were described so that this disclosure is thorough and complete, and fully conveys the inventive concept to those skilled in the art. Thus, the true spirit and scope of the inventive concept is not limited by the embodiment and examples described above but by the following claims.

1. A three-dimensional (3D) image sensor, comprising:
a substrate including a first pixel region and a second pixel region;
a first photoelectric converter in the first pixel region of the substrate;
a second photoelectric converter in the second pixel region of the substrate;
a first transfer gate disposed on the substrate at one side of the first photoelectric converter, and a first transfer gate insulating layer interposed between the first transfer gate and the substrate;
a second transfer gate disposed on the substrate at one side of the second photoelectric converter, and a second transfer gate insulating layer interposed between the second transfer gate and the substrate; and
a drain gate disposed on the substrate at other side of the second photoelectric converter, and a drain gate insulating layer interposed between the second transfer gate and the substrate, and
wherein the second transfer gate insulating layer and the drain gate insulating layer each have a thickness different from that of the first transfer gate insulating layer.

2. The 3D image sensor of claim 1, wherein the second transfer gate insulating layer and the drain gate insulating layer are each thinner than the first transfer gate insulating layer.

3. The 3D image sensor of claim 2, further comprising:
a reset gate disposed on the substrate and spaced apart from one of transfer gates; and
a reset gate insulating layer interposed between the reset gate and the substrate, and
wherein the second transfer gate insulating layer and the drain gate insulating layer are each thinner than the reset gate insulating layer.

4. The 3D image sensor of claim 3, further comprising:
a source follower gate disposed on the substrate and spaced apart from the reset gate; and
a source follower gate insulating layer interposed between the source follower gate and the substrate, and
wherein the second transfer gate insulating layer and the drain gate insulating layer are each thinner than the source follower gate insulating layer.

5. The 3D image sensor of claim 4, further comprising:
a selection gate disposed on the substrate and spaced apart from the source follower gate; and
a selection gate insulating layer interposed between the selection gate and the substrate, and
wherein the second transfer gate insulating layer and the drain gate insulating layer are each thinner than the selection gate insulating layer.

6. The 3D image sensor of claim 2, wherein the first transfer gate insulating layer, the reset gate insulating layer, the source follower gate insulating layer, and the selection gate insulating layer have substantially the same thicknesses.

7. The 3D image sensor of claim 1, wherein each of the second transfer gate insulating layer and the drain gate insulating layer consists of a single layer of material, and
the first transfer gate insulating layer is a multi-layered structure including two layers of material.

8. The 3D image sensor of claim 1, wherein the second transfer gate insulating layer and the drain gate insulating layer have substantially the same thicknesses.

9. The 3D image sensor of claim 1, wherein the first photoelectric converter is configured to detect visible light rays, and the second photoelectric converter is configured to detect infrared rays.

10. The 3D image sensor of claim 1, and configured to operate the drain gate and the second transfer gate reversely with respect to each other.

11. A 3D image sensor, comprising:
a semiconductor substrate;
a device isolation layer in the substrate and defining a first active region and a second active region;
a color pixel configured to output color information of an object; and
a depth pixel configured to output information on the relative depth of the object, and
wherein the color pixel includes a first transfer gate electrode on the first active region, first transfer gate insulation interposed between and contacting the first transfer gate electrode and the first active region, a first photoelectric converter that converts light to electrical signals, and a first floating diffusion region,
the first photoelectric converter includes a region of impurities located in the first active region and extending at one side of the first transfer gate electrode,
the first floating diffusion region is located in the first active region at the other side of the first transfer gate electrode,
the depth pixel includes a second transfer gate electrode disposed on the second active region, second transfer gate insulation interposed between and contacting the second transfer gate electrode and the second active region, a second floating diffusion region, a drain gate electrode disposed on the second active region, drain gate insulation interposed between the drain gate electrode and the second active region, a drain region, and a second photoelectric converter that converts light to electrical signals,
the second photoelectric converter includes a region of impurities in the second active region and extending to one side each of the second transfer gate electrode and the drain gate electrode,
the second floating diffusion region is located in the second active region at the other side of the second transfer gate electrode,
the drain region is located in the second active region at the other side of the drain gate electrode, and
at least one of the drain gate insulation and the second transfer gate insulation is thinner than the first transfer gate insulation, as taken in the direction between the gate electrodes and the active regions.

12. The 3D image sensor of claim 11, wherein the second transfer gate insulation and the drain gate insulation are each thinner than the first transfer gate insulation.

13. The 3D image sensor of claim 12, further comprising:
a reset gate electrode disposed on the substrate and spaced apart from one of transfer gate electrodes; and
reset gate insulation interposed between and contacting the reset gate electrode and the substrate, and
wherein the second transfer gate insulation and the drain gate insulation are each thinner than the reset gate insulating layer.

14. The 3D image sensor of claim 13, further comprising:
a source follower gate electrode disposed on the substrate and spaced apart from the reset gate electrode; and
source follower gate insulation interposed between and contacting the source follower gate electrode and the substrate, and
wherein the second transfer gate insulation and the drain gate insulation are each thinner than the source follower gate insulation.

15. The 3D image sensor of claim 14, further comprising:
a selection gate electrode disposed on the substrate and spaced apart from the source follower gate electrode; and
selection gate insulation interposed between and contacting the selection gate electrode and the substrate, and
wherein the second transfer gate insulation and the drain gate insulation are each thinner than the selection gate insulation.

16. The 3D image sensor of claim 15, wherein the first transfer gate insulation, the reset gate insulation, the source follower gate insulation, and the selection gate insulation have substantially the same thicknesses.

17. The 3D image sensor of claim 11, wherein the second transfer gate insulation and the drain gate insulation have substantially the same thicknesses.

18. An imaging device comprising the 3D image sensor of claim 11, and a light source for illuminating an object whose image is captured by the 3D image sensor.

19-20. (canceled)
